(19) United States
(12) Patent Application Publication
(10) Pub. No.: US 2002/0162071 A1
(43) Pub. Date: Oct. 31, 2002

(54) Forward error control of redundantly-transmitted codewords

(76) Inventor: Shih-Jeh Chang, Naperville, IL (US)

Correspondence Address: DEMONT & BREYER, LLC, PO BOX 7490, SHREWSBURY, NJ, 07702, US

(21) Appl. No.: 09/791,260

(22) Filed: Feb. 22, 2001

(51) Int. Cl. H03M 13/00; G06F 11/00

(52) U.S. Cl. 714/777; 714/800

(57) ABSTRACT

A method of forward error control is disclosed in which a transmitter receives data from an input device and from it creates one or more original codewords pursuant to an error-control coding scheme. The transmitter then transmits a copy of the original codeword onto each of two physically distinct telecommunications channels for delivery to the intended receiver. The receiver then checks the validity of the estimates of the original codewords that it receives. If at least one received estimate of the original codeword that is deemed to be valid, then the receiver uses it. Alternatively, when the both of the received estimates of the original codeword are deemed invalid (because they have been both corrupted), then the receiver begins the process of constructing a final estimate of the original codeword based on the both of the received estimates.

### CROSS-REFERENCE TO RELATED APPLICATIONS

This application is related to U.S. patent application Ser. No. 09/______ ,_______ , filed on the same day as this application and entitled “Redundant Packet Network Architecture” (Attorney Docket S. J. Chang 11), which application is incorporated by reference.

### FIELD OF THE INVENTION

The present invention relates to telecommunications in general, and, more particularly, to forward error control in packet networks.

### BACKGROUND OF THE INVENTION

The problem of dealing with transmission errors in telecommunications networks has been studied for many years. In general, the solutions for dealing with transmission errors fall into two classes: (i) forward error control, and (ii) automatic-repeat-request.

In accordance with forward error control, data is encoded in accordance with an error-control coding scheme that increases the likelihood that the receiver can detect and correct any errors that might occur during transmission.

In accordance with automatic-repeat-request, data is encoded in accordance with an error-control coding scheme that that enables the receiver to detect, but not correct, errors that occur during transmission. In accordance with automatic-repeat-request, when an error is detected, the receiver transmits a message back to the transmitter requesting that the data be re-transmitted. This cycle continues until the receiver believes that the data has been received without error.

Both forward error control and automatic-repeat-request have advantages and disadvantages. The advantage of forward error control is that it avoids the temporal delay associated with automatic-repeat-request. The advantage of automatic-repeat-request is that its error-control coding schemes typically require a lower data bit-to-parity bit ratio (i.e., less redundancy), and, therefore, less bandwidth in the communications channels.

There exist applications, however, where the prior art techniques of forward error control and automatic-repeat-request are unsatisfactory. One of these applications is Internet telephony, which is also known as voice over Internet. In Internet telephony, the temporal delay associated with automatic-repeat-request causes unsatisfactory interruptions in the preferably continuous flow of speech. Although this problem can generally be avoided by using error-correction coding schemes, error-correction schemes are ineffective when packets containing voice data are lost or delayed during transmission.

Therefore, the need exists for an improved technique for dealing with transmission errors in telecommunications networks that is particularly advantageous for Internet telephony applications.

### SUMMARY OF THE INVENTION

Some embodiments of the present invention deal with transmission errors in telecommunications networks without some costs and disadvantages associated with techniques in the prior art. In particular, the illustrative embodiment of the present invention incorporates a forward error control mechanism that deals with lost, delayed, or corrupted packets.

In accordance with the illustrative embodiment of the present invention, a transmitter receives data from an input device and from it creates one or more original codewords pursuant to an error-control coding scheme. For example, the transmitter can receive audio data from a microphone and can convert that audio data into one or more original codewords.

The transmitter then transmits a copy of the original codeword onto each of two physically distinct telecommunications channels for delivery to the intended receiver. The reason that two copies of the original codeword are transmitted to the receiver via physically distinct channels is to increase the robustness of the overall effective telecommunications channel between the transmitter and the receiver, and to decrease the elapsed time between when the transmitter transmits the original codeword and when the receiver receives the estimate of the original codeword.

The receiver then checks the validity of the estimates of the original codewords that it receives, in accordance with the error-control coding scheme with which the original codeword was encoded. If at least one received estimate of the original codeword that is deemed to be valid, then the receiver uses it. For example, if the codeword comprises audio data, the receiver can output that audio data via a speaker.

Alternatively, when the both of the received estimates of the original codeword are deemed invalid (because they have been both corrupted), then the receiver begins the process of constructing a final estimate of the original codeword based on the both of the received estimates. In particular, this is accomplished by constructing a final estimate of the original codeword by selecting a valid codeword in the error-control coding scheme such that the Hamming distance between the final estimate of the original codeword and the first estimate of the original codeword plus the Hamming distance between the final estimate of the original codeword and the second estimate of the original codeword is a minimum.

When there is a single candidate codeword with the minimum sum of the Hamming distances, that candidate codeword is chosen as the final estimate of the original codeword. When, as in the present example, there is more than one candidate codeword with the minimum sum of the Hamming distances, there are several alternative methods for choosing the final estimate of the original codeword.

The illustrative embodiment comprises: transmitting a first copy of an original codeword from a transmitter to a receiver via a first point-to-point telecommunications channel; transmitting a second copy of said original codeword from said transmitter to said receiver via a second point-to-point telecommunications channel; receiving at said receiver a first estimate of said original codeword from said first point-to-point telecommunications channel; and constructing a final estimate of said original codeword based on said first estimate of said original codeword.

### BRIEF DESCRIPTION OF THE DRAWINGS

FIG. 1 depicts a schematic diagram of a redundant packet network in accordance with the illustrative embodiment of the present invention.

FIG. 2 depicts a flowchart that describes the operation and interaction of the elements depicted in FIG. 1 in accordance with the illustrative embodiment of the present invention.

FIG. 3 depicts a perspective drawing of a cube in which each of the eight vertices of the cube is uniquely associated with one of the eight codewords in the illustrative error-control coding scheme.

FIG. 4 depicts a block diagram of the salient components of receiver 102 in FIG. 1.

FIG. 5 depicts a perspective drawing of the cube in FIG. 3, and highlights the three vertices (and corresponding valid codewords) that are nearest geometrically (and in Hamming distance) to the two vertices that are associated with invalid codewords.

### DETAILED DESCRIPTION

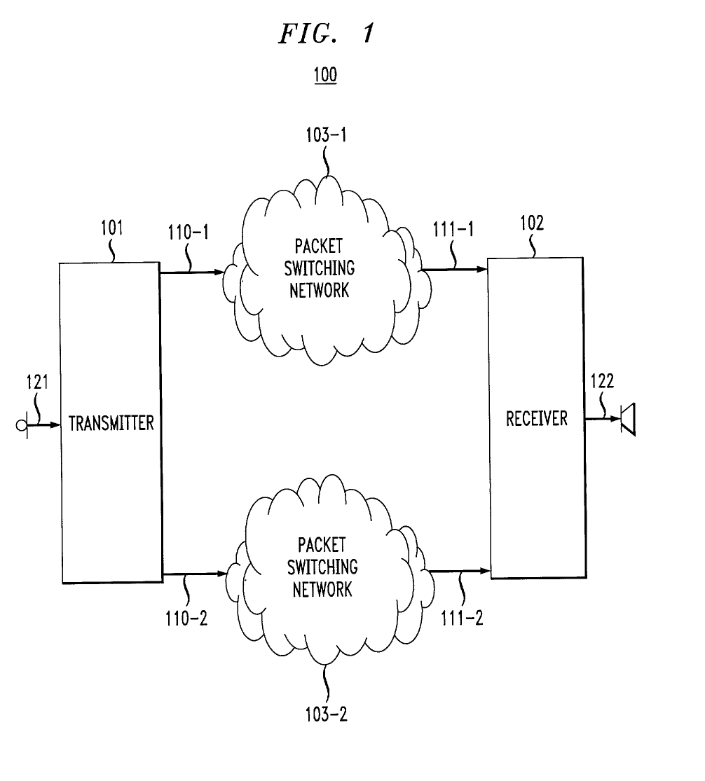

FIG. 1 depicts a schematic diagram of redundant packet network 100 in accordance with the illustrative embodiment of the present invention. Redundant packet network 100 comprises: transmitter 101 and receiver 102 connected by two logically and physically distinct point-to-point telecommunications channels. The first point-to-point telecommunications channel comprises: physical telecommunications path 110-1, packet switching network 103-1, and physical telecommunications path 111-1. The second point-to-point telecommunications channel comprises: physical telecommunications path 110-2, packet switching network 103-2, and physical telecommunications path 111-2. The input to transmitter 101 is microphone 121, and the output from receiver 102 is speaker 122.

In accordance with the illustrative embodiment of the present invention, each of the first point-to-point telecommunications channel and the second point-to-point telecommunications channel is a “point-to-point” telecommunications channel. For the purposes of this specification, a “point-to-point telecommunications channel” is defined as a conduit for carrying a signal from one entity (e.g., a transmitter, etc.) to another entity (e.g., a receiver, etc.) for which it is intended. Typically, the signals in a point-to-point telecommunications channel are explicitly associated with the address or identification of the entity for which the signals are intended. Furthermore, the signals in a point-to-point telecommunications channel are often also explicitly associated with the address or identification of the point-to-point telecommunications channel in which they are carried.

It will be understood by those skilled in the art that a point-to-point telecommunications channel is not a point-to-multipoint (i.e., broadcast) telecommunications channel, which is a logical conduit for carrying a signal from one entity (e.g., a transmitter, etc.) to a plurality of entities (e.g., a receiver, etc.). The signals in a point-to-multipoint telecommunications channel are not associated with the address or identification of the entity for which the signals are intended. Furthermore, the signals in a point-to-multipoint telecommunications channel are not explicitly associated with the address or identification of the point-to-multipoint telecommunications channel in which they are carried.

In accordance with the illustrative embodiment of the present invention, each point-to-point telecommunication channel can comprise a series of wireline or wireless or both wireline and wireless telecommunications links. It will understood by those skilled in the art that the presence of wireless telecommunications links in a given telecommunications channel does not suggest or imply, in and of itself, that the telecommunications channel is either point-to-point or point-to-multipoint.

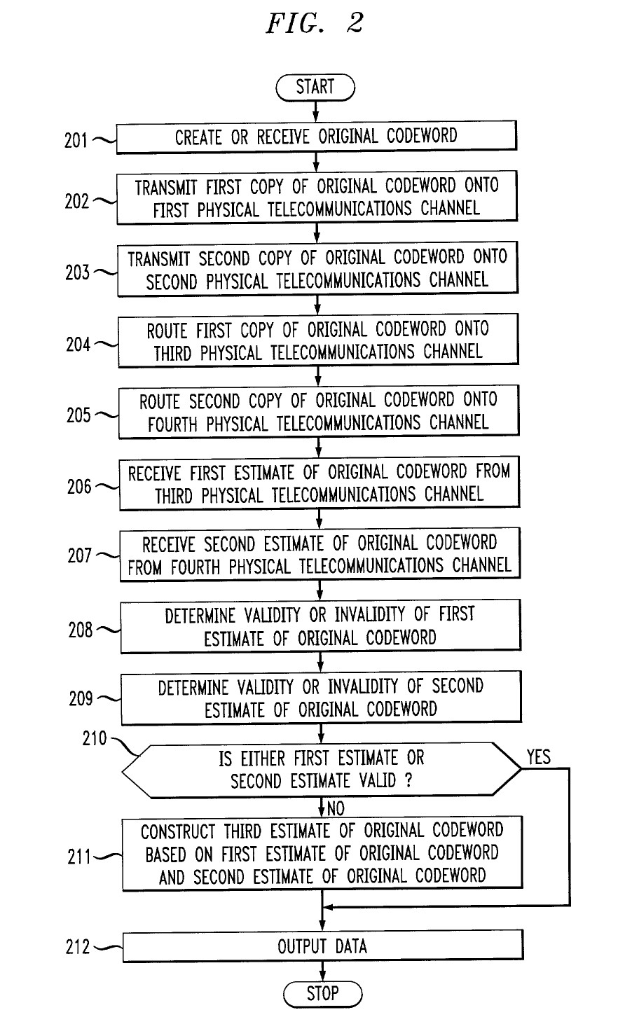

FIG. 2 depicts a flowchart that describes the operation and interaction of the elements depicted in FIG. 1 in accordance with the illustrative embodiment of the present invention.

At step 201, transmitter 101 receives data from an input device in well-known fashion and from it creates one or more original codewords. To do this, transmitter 101 creates one or more message blocks, each of which comprises k arbitrary message bits, m₀, m₁, . . . , mₖ₋₁, based on the input data. For example, transmitter 101 can receive audio data from microphone 121 and can convert that audio data into one or more message blocks.

Each message block is then applied to an error-control coding scheme, in well-known fashion, to produce an n-bit codeword (wherein n>m) that is a valid codeword within the context of that error-control coding scheme. For the purposes of this specification, an “error-control coding scheme” is defined as a system for enabling the detection or correction of the corruption of one or more symbols in a codeword. As is well-known to those skilled in the art, the n−m bits in the n-bit codeword represent redundancy that enable valid codewords in an error-control coding scheme to be distinguished from invalid codewords.

Advantageously, embodiments of the present invention use block error-control coding schemes (e.g., Hamming codes, cyclic codes, Bose-Chaudhuri-Hocquenghem codes, Reed-Solomon Codes, etc.) in contrast to convolutional error-control coding schemes (e.g., trellis coding, etc.) for reasons that will be clear to those skilled in the art after reading this specification. The illustrative embodiment of the present invention uses a simple block error-control coding scheme to facilitate an understanding of the present invention. The illustrative error-control coding scheme is, however, sophisticated enough to illustrate all of the inventive principals underlying the present invention, and it will be clear to those skilled in the art, after reading this specification, how to make and use embodiments of the present invention that use any error-control coding scheme.

The error-control coding scheme in accordance with the illustrative embodiment of the present invention comprises a 3-bit codeword, which itself comprises 2 message bits and 1 parity bit. Table 1 depicts the format of a codeword in accordance with the illustrative embodiment.

TABLE 1
Codeword Format

| | | |
|---|---|---|
| c₀ | c₁ | c₂ |

Codeword bit co equals message bit m₀, codeword bit c₁ equals message bit m₁, and codeword bit c₂ is a parity bit that is chosen to force the modulo 2 sum of c₀, c₁, and c₂ to be an even number (i.e., even parity). As will be clear to those skilled in the art, this error-control coding scheme enables only single-bit error detection. Table 2 depicts a list of all eight (i.e., 2³) codewords in accordance with the illustrative embodiment.

TABLE 2
List of All Codewords

| c₀ | c₁ | c₂ | Valid Codeword in Scheme? | Message Block |
|---|---|---|---|---|
| 0 | 0 | 0 | Yes | m₀ = 0, m₁ = 0 |
| 0 | 0 | 1 | No | — |
| 0 | 1 | 0 | No | — |
| 0 | 1 | 1 | Yes | m₀ = 0, m₁ = 1 |
| 1 | 0 | 0 | No | — |
| 1 | 0 | 1 | Yes | m₀ = 1, m₁ = 0 |
| 1 | 1 | 0 | Yes | m₀ = 1, m₁ = 1 |
| 1 | 1 | 1 | No | — |

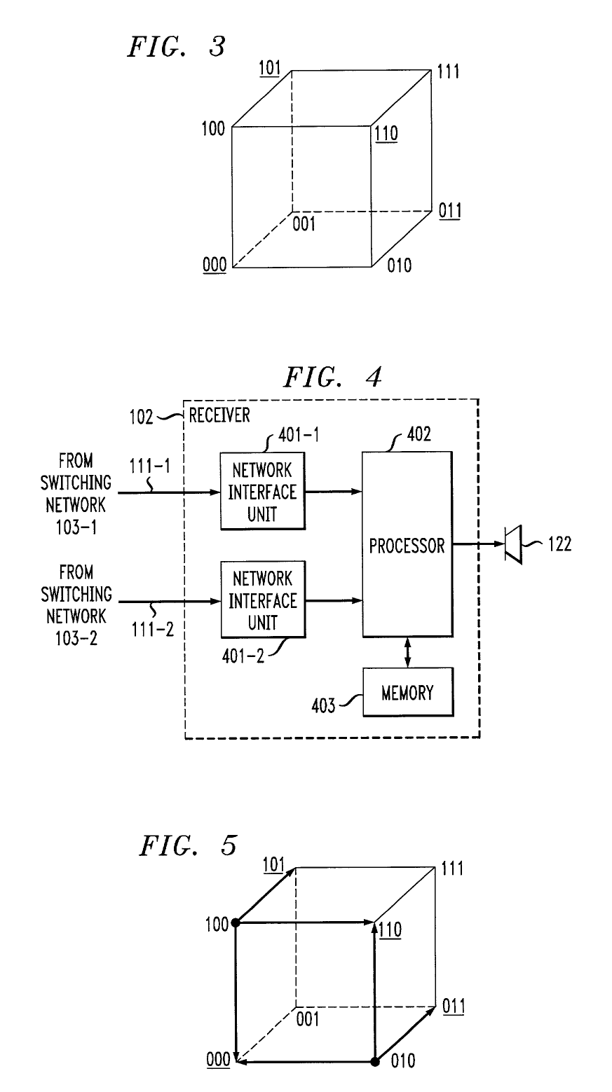

FIG. 3 depicts a perspective drawing of a cube in which each of the eight vertices of the cube is uniquely associated with one of the eight codewords in the illustrative error-control coding scheme in such a way that the Hamming distance between codewords at adjacent vertices is one. For the purposes of this specification, the phrase “Hamming distance” is defined as the number of symbol positions in which two codewords differ. The underlined codewords in FIG. 3 represent the valid code words in accordance with the illustrative error-control scheme. From FIG. 3 it can be observed that there are no two valid codewords on adjacent vertices and the change of any bit in any valid codeword creates an invalid codeword that is on a vertex that is adjacent to the vertex associated with the valid codeword.

In some alternative embodiments of the present invention, transmitter 101 receives one or more codewords from another apparatus, which is not depicted in FIG. 1.

At step 202, transmitter 101 transmits a first copy of the original codeword onto physical telecommunications channel 110-1 for delivery to receiver 102 via packet switching network 103-1 and physical telecommunications channel 111-1. Physical telecommunications channel 110-1 can be either a wireless or wireline channel, and can be either dedicated or multiplexed with other traffic. It will be clear to those skilled in the art how to implement step 202.

At step 203, transmitter 101 transmits a second copy of the original codeword onto physical telecommunications channel 110-2 for delivery to receiver 102 via packet switching network 103-2 and physical telecommunications channel 111-2. Physical telecommunications channel 110-2 can be either a wireless or wireline channel, and can be either dedicated or multiplexed with other traffic. It will be clear to those skilled in the art how to implement step 203.

In accordance with the illustrative embodiment of the present invention, two copies of the original codeword are transmitted to receiver 102 via physically distinct channels to:

1. increase the robustness of the logical telecommunications channel between transmitter 101 and receiver 102, and

2. decrease the elapsed time between when transmitter 101 transmits the original codeword and when receiver 101 has available a final estimate of the original codeword.

Although physical telecommunications channel 111-1 and physical telecommunications channel 111-1 are advantageously physically distinct, packet switching network 103-1 and packet switching network 111-1 can be either the one packet switching network or different packet switching networks. When packet switching network 103-1 and packet switching network 111-1 are one packet switching network, it is still advantageous for the first copy of the codeword and the second copy of the codeword to traverse different physical routes from transmitter 101 to receiver 102. It will be clear to those skilled in the art that step 202 might occur before step 203, after step 203, or concurrently with step 203.

At step 204, packet switching network 103-1 receives the first copy of the original codeword, or, more precisely, an estimate of the original codeword from physical telecommunications channel 110-1. It is more accurate to consider what packet switching network 103-1 receives to be an estimate of the original codeword rather than an absolutely true facsimile of the codeword because one or more bits in the codeword might have been corrupted in transit on physical telecommunications channel 110-1. When packet switching network 103-2 receives the estimate of the original codeword, it routes the estimate to receiver 102 via physical telecommunications channel 111-1. Physical telecommunications channel 111-1 can be either a wireless or wireline channel, and can be either dedicated or multiplexed with other traffic.

At step 205, and for the reasons given with respect to step 204 above, packet switching network 103-2 receives an estimate of the original codeword from physical telecommunications channel 110-2 and routes it to receiver 102 via physical telecommunications channel 111-2. Physical telecommunications channel 111-2 can be either a wireless or wireline channel, and can be either dedicated or multiplexed with other traffic. It will be clear to those skilled in the art that step 204 might occur before step 205, after step 205, or concurrently with step 205. In any case, it will be clear to those skilled in the art how to implement steps 204 and 205.

At step 206, receiver 102 receives the first estimate of the original codeword from physical telecommunications channel 111-1. FIG. 4 depicts a block diagram of the components of receiver 102 that facilitate and understanding of the present invention.

As shown in FIG. 4, receiver 102 advantageously comprises: network interface unit 401-1, network interface unit 401-2, processor 402, and memory 403. Network interface unit 401-1 advantageously comprises the circuitry to enable receiver 102 to receive the first estimate of the original codeword from physical telecommunications channel 111-1 and to provide it to processor 402. Similarly, network interface unit 401-2 advantageously comprises the circuitry to enable receiver 102 to receive the second estimate of the original codeword from physical telecommunications channel 111-2 and to provide it to processor 402. Processor 402 is either a general-purpose processor or a special-purpose processor that is capable of performing the functionality described herein and with respect to steps 206 through 212. Memory 403 advantageously stores the programs and data used by processor 402 in performing steps 206 through 212. After reading this specification, it will be clear to those skilled in the art how to make and use network interface unit 401-1, network interface unit 401-2, processor 402, and memory 403.

At step 207, receiver 102 receives the second estimate of the original codeword from physical telecommunications channel 111-2. It will be clear to those skilled in the art that step 206 might occur before step 207, after step 207, or concurrently with step 207. In any case, it will be clear to those skilled in the art how to implement steps 206 and 207.

At step 208, receiver 102 determines the validity or invalidity of the first estimate of the original codeword, in well-known fashion and in accordance with the particular error-control coding scheme chosen in step 201, to determine if it has been corrupted in transfer from transmitter 101. For example, if the first estimate of the original codeword is “001, ” Table 2 and FIG. 3 both indicate that “101” is an invalid codeword. Alternatively, if the first estimate of the original codeword is “101, ” then both Table 2 and FIG. 3 both indicate that “101” is a valid codeword. As will be clear to those skilled in the art, the receipt of a “valid” codeword does not guarantee that the codeword was not corrupted in transit, but that, within the limitations of the chosen error-control coding scheme, no corruption is evident.

At step 209, receiver 102 determines the validity or invalidity of the second estimate of the original codeword, in well-known fashion, to determine if it has been corrupted in transfer from transmitter 101. Step 208 might occur before step 209, after step 209, or concurrently with step 209. In any case, it will be clear to those skilled in the art how to implement steps 208 and 209.

At step 210, receiver 102 determines if either the first estimate of the original codeword or the second estimate of the original codeword is valid. If either estimate is valid, then either estimate, if both are valid, or the valid estimate, if only one is valid, is deemed to be the final estimate and control proceeds to step 212; alternatively, control proceeds to step 211.

Control only proceeds to step 211 when neither first estimate of the original codeword nor the second estimate of the original codeword is valid within the context of the chosen error-control coding scheme. Therefore, at step 211, receiver 102 begins the process of constructing a final estimate of the original codeword based on the corrupted first estimate of the original codeword and the corrupted second estimate of the original codeword. In particular, this is accomplished by constructing a final estimate of the original codeword by selecting a valid codeword in the error-control coding scheme such that the Hamming distance between the final estimate of the original codeword and the first estimate of the original codeword plus the Hamming distance between the final estimate of the original codeword and the second estimate of the original codeword is a minimum.

To illustrate this process with an example, assume that the original codeword is “000, ” the first (invalid) estimate of the original codeword as received by receiver 102 is “100, ” and the second (invalid) estimate of the original codeword as received by receiver 102 is “010. ” From both Table 2 and FIG. 3 it can be seen that neither the first estimate of the original codeword nor the second estimate of the original codeword is valid.

In accordance with the illustrative embodiment of the present invention, all valid codewords are compared with the first estimate of the original codeword and the second estimate of the original codeword, the Hamming distance between each pair is computed and the sum of the Hamming distances is computed. Table 3 depicts the outcome in each step of this process.

TABLE 3
Comparison of Candidate Codewords

| | | Hamming | | Hamming | |
|---|---|---|---|---|---|
| | First | Distance | Second | Distance | |
| | Estimate | Between | Estimate | Between | |
| | of | Candidate | of | Candidate | Sum of |
| Candidate | Original | and First | Original | and Second | Hamming |
| Codeword | Codeword | Estimate | Codeword | Estimate | Distance |
| 000 | 100 | 1 | 010 | 1 | 2 |
| 011 | 100 | 3 | 010 | 1 | 4 |
| 101 | 100 | 1 | 010 | 3 | 4 |
| 110 | 100 | 1 | 010 | 1 | 2 |

FIG. 5 depicts the cube of FIG. 3 that illustrates the results shown in Table 3 and facilitates an understanding of why in the present example the candidate codewords “000” and “110” are more likely to be correct than are the candidate codewords “101” and “001”. In FIG. 5, both invalid codewords “100” and “010” are adjacent to valid codewords “000” and “110, ” whereas only one of invalid codewords “100” and “010” are adjacent to candidate codewords “101” and “001.”

In accordance with the illustrative embodiment, the final estimate of the original codeword is deemed to be the valid codeword that has the minimum Hamming distance between the final estimate of the original codeword and the first estimate of the original codeword plus the Hamming distance between the final estimate of the original codeword and the second estimate of the original codeword. When there is a single candidate codeword with the minimum sum of the Hamming distances, that candidate codeword is chosen as the final estimate of the original codeword.

When, as in the present example, there is more than one candidate codeword with the minimum sum of the Hamming distances, there are several alternative methods for choosing the final estimate of the original codeword. In the present example, two candidate codewords, “000” and “110” both have the minimum of the Hamming distances.

First, the final estimate of the original codeword can be chosen randomly from among the candidate codewords with the minimum sum of the Hamming distances. Although this method can produce a final estimate of the original codeword that is incorrect, it is more likely to correctly guess the original codeword than is any guess that based upon either the first (invalid) estimate of the original codeword or the second (invalid) estimate of the original codeword alone.

Second, the final estimate of the original codeword can be chosen by comparing each of the candidate codewords with the minimum sum of the Hamming distances against the final estimates of one or more of the previously received original codewords. The theory underlying this method is that if there is a pattern in the previously received original codewords that suggests that one of the candidate codewords with the minimum sum of the Hamming is more likely than the others, it is chosen as the final estimate of the original codeword.

At step 212, receiver 102 outputs the final estimate of the original codeword, whether it was determined in step 210 or in step 211, in well-known fashion. For example, when the original codeword represents audio data, receiver 102 might output the audio data to speaker 122.

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. A method comprising:
receiving a first estimate of an original codeword from a first physical telecommunications channel, wherein said original codeword is a valid codeword in an error-control coding scheme;
receiving a second estimate of said original codeword from a second physical telecommunications channel;
determining that said first estimate of said original codeword is an invalid codeword in said error-control coding scheme;
determining that said second estimate of said original codeword is an invalid codeword in said error-control coding scheme; and
constructing a final estimate of said original codeword by selecting a valid codeword in said error-control coding scheme such that the Hamming distance between said final estimate of said original codeword and said first estimate of said original codeword plus the Hamming distance between said final estimate of said original codeword and said second estimate of said original codeword is a minimum.

2. The method of claim 1 wherein said error-control coding scheme comprises a parity bit.

3. The method of claim 1 wherein said error-control coding scheme comprises a block code.

4. The method of claim 1 wherein said error-control coding is an error-detection code.

5. The method of claim 1 wherein said first codeword comprises n bits and said second codeword comprises n bits; and wherein said original codeword represents audio data.

6. The method of claim 1 further comprising:
transmitting a first copy of said original codeword from a transmitter onto said first physical telecommunications channel; and
transmitting a second copy of said original codeword from said transmitter onto said second physical telecommunications channel.

7. An apparatus comprising:
a receiver receiving a first estimate of an original codeword from a first physical telecommunications channel, wherein said original codeword is a valid codeword in an error-control coding scheme, and for receiving a second estimate of said original codeword from a second physical telecommunications channel; and
a processor for determining that said first estimate of said original codeword is an invalid codeword in said error-control coding scheme, for determining that said second estimate of said original codeword is an invalid codeword in said error-control coding scheme, and for constructing a final estimate of said original codeword by selecting a valid codeword in said error-control coding scheme such that the Hamming distance between said final estimate of said original codeword and said first estimate of said original codeword plus the Hamming distance between said final estimate of said original codeword and said second estimate of said original codeword is a minimum.

8. The apparatus of claim 7 wherein said error-control coding scheme comprises a parity bit.

9. The apparatus of claim 7 wherein said error-control coding scheme comprises a block code.

10. The apparatus of claim 7 wherein said error-control coding is an error-detection code.

11. The apparatus of claim 7 wherein said first codeword comprises n bits and said second codeword comprises n bits; and wherein said original codeword represents audio data.

12. The apparatus of claim 7 further comprising:
a transmitter for transmitting a first copy of said original codeword from a transmitter onto said first physical telecommunications channel, and for transmitting a second copy of said original codeword from said transmitter onto said second physical telecommunications channel.

13. A method comprising:
determining that said first estimate of a original codeword is an invalid codeword in said error-control coding scheme, wherein said original codeword is a valid codeword in said error-control coding scheme;
determining that said second estimate of said original codeword is an invalid codeword in said error-control coding scheme; and
constructing a final estimate of said original codeword by selecting a valid codeword in said error-control coding scheme such that the Hamming distance between said final estimate of said original codeword and said first estimate of said original codeword plus the Hamming distance between said final estimate of said original codeword and said second estimate of said original codeword is a minimum.

14. The method of claim 13 wherein said error-control coding scheme comprises a parity bit.

15. The method of claim 13 wherein said error-control coding scheme comprises a block code.

16. The method of claim 13 wherein said error-control coding is an error-detection code.

17. The method of claim 13 wherein said first codeword comprises n bits and said second codeword comprises n bits; and wherein said original codeword represents audio data.
